(19) United States
(12) Patent Application Publication
(10) Pub. No.: US 2021/0265820 A1
(43) Pub. Date: Aug. 26, 2021

(54) Semiconductor Laser And Atomic Oscillator

(71) Applicant: Seiko Epson Corporation, Tokyo (JP)

(72) Inventors: Yasuto KAKEMURA, Kai (JP); Masamitsu MOCHIZUKI, Chino (JP); Takahiro AMANO, HARA-MURA (JP)

(21) Appl. No.: 17/183,526

(22) Filed: Feb. 24, 2021

(30) Foreign Application Priority Data
Feb. 25, 2020 (JP) 2020-029220
Feb. 12, 2021 (JP) 2021-020821

(51) Int. Cl. H01S 5/183; H03L 7/26

(52) U.S. Cl. CPC H01S 5/18375; H03L 7/26; H01S 5/18311

(57) ABSTRACT

A semiconductor laser includes a first mirror layer, a second mirror layer, an active layer, a first area provided continuously with the first mirror layer and including a plurality of first oxidized layers, and a second area provided continuously with the second mirror layer and including a plurality of second oxidized layers. The first mirror layer, the second mirror layer, the active layer, the first area, and the second area form a laminate. The laminate includes in the plan view a first section, a second section, and a third section disposed between the first section and the second section along a first axis and causing light produced in the active layer to resonate. The amount of strain per unit volume in the second mirror layer of the third section is measured along a second axis perpendicular to the first axis and passing through the center of the third section in the plan view, and the difference between the maximum of the amount of strain and the minimum thereof is smaller than 0.20%.

The present application is based on, and claims priority from JP Application Serial Number 2020-029220, filed Feb. 25, 2020, and JP Application Serial Number 2021-020821, filed Feb. 12, 2021, the disclosures of which are hereby incorporated by reference herein in their entirety.

### BACKGROUND

### 1. Technical Field

The present disclosure relates to a semiconductor laser and an atomic oscillator.

### 2. Related Art

A surface emitting semiconductor laser is used, for example, as the light source of an atomic oscillator using coherent population trapping (CPT), which is one of quantum interference effects. Such a semiconductor laser includes two mirror layers and an active layer disposed between the two mirror layers.

The resonator of a surface emitting semiconductor laser typically has an isotropic structure, and it is therefore difficult to control the polarization of the light outputted from the resonator. JP-A-2015-119136 describes that a strain imparter that imparts strain to a resonance section is provided to polarize the light.

The semiconductor laser provided with the strain imparter described above can control the polarization of the light from the semiconductor laser, but it is difficult to control stress induced by the strain imparter. When unexpected stress is induced in the mirror layers of the resonance section, dislocation occurs.

### SUMMARY

A semiconductor laser according to an aspect of the present disclosure includes a first mirror layer, a second mirror layer, an active layer disposed between the first mirror layer and the second mirror layer, a first area provided continuously with the first mirror layer and including a plurality of first oxidized layers, and a second area provided continuously with the second mirror layer and including a plurality of second oxidized layers. The first mirror layer, the second mirror layer, the active layer, the first area, and the second area form a laminate. The laminate includes in the plan view a first section, a second section, and a third section disposed between the first section and the second section along a first axis and causing light produced in the active layer to resonate. An amount of strain per unit volume in the second mirror layer of the third section is measured along a second axis perpendicular to the first axis and passing through a center of the third section in the plan view, and a difference between a maximum of the amount of strain and a minimum thereof is smaller than 0.20%.

An atomic oscillator according to an aspect of the present disclosure includes a semiconductor laser, an atomic cell irradiated with light outputted from the semiconductor laser and accommodating an alkali metal atom, and a light receiver that detects intensity of light passing through the atomic cell and outputs a detection signal. The semiconductor laser includes a first mirror layer, a second mirror layer, an active layer disposed between the first mirror layer and the second mirror layer, a first area provided continuously with the first mirror layer and including a plurality of first oxidized layers, and a second area provided continuously with the second mirror layer and including a plurality of second oxidized layers. The first mirror layer, the second mirror layer, the active layer, the first area, and the second area form a laminate. The laminate includes in the plan view a first section, a second section, and a third section disposed between the first section and the second section along a first axis and causing light produced in the active layer to resonate. An amount of strain per unit volume in the second mirror layer of the third section is measured along a second axis perpendicular to the first axis and passing through a center of the third section in the plan view, and a difference between the maximum of the amount of strain and the minimum thereof is smaller than 0.20%.

### BRIEF DESCRIPTION OF THE DRAWINGS

FIG. 1 is a plan view diagrammatically showing a semiconductor laser according to an embodiment of the present disclosure.

FIG. 2 is a cross-sectional view diagrammatically showing the semiconductor laser according to the present embodiment.

FIG. 3 is a plan view diagrammatically showing the semiconductor laser according to the present embodiment.

FIG. 4 is a cross-sectional view diagrammatically showing the semiconductor laser according to the present embodiment.

FIG. 5 is a view explaining an amount of strain.

FIG. 6 is a cross-sectional view diagrammatically showing one of the steps of manufacturing the semiconductor laser according to the present embodiment.

FIG. 7 is a cross-sectional view diagrammatically showing another of the steps of manufacturing the semiconductor laser according to the present embodiment.

FIG. 8 is a cross-sectional view diagrammatically showing another of the steps of manufacturing the semiconductor laser according to the present embodiment.

FIG. 9 shows the configuration of an atomic oscillator according to the present embodiment.

FIG. 10 describes an example of a frequency signal generation system according to the present embodiment.

FIG. 11 shows a graph illustrating a line profile of the amount of strain.

FIG. 12 shows a graph illustrating a line profile of the amount of strain.

FIG. 13 shows a graph illustrating a line profile of the amount of strain.

FIG. 14 show graphs illustrating the relationship between Al atom concentration and the difference between the maximum of the amount of strain and the minimum thereof.

FIG. 15 shows graphs illustrating the relationship between the Al atom concentration and a polarization difference ratio.

### DESCRIPTION OF EXEMPLARY EMBODIMENTS

A preferable embodiment of the present disclosure will be described below in detail with reference to the drawings. It is not intended that the embodiment described below unduly limits the contents of the present disclosure set forth in the appended claims. Further, all configurations described below are not necessarily essential configuration requirements of the present disclosure.

### 1. Semiconductor Laser

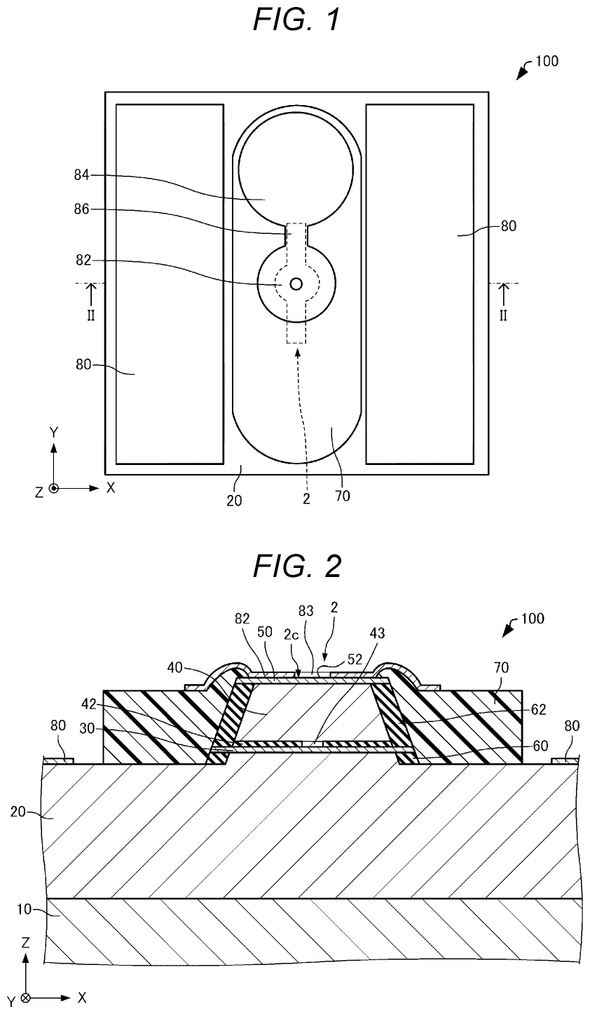

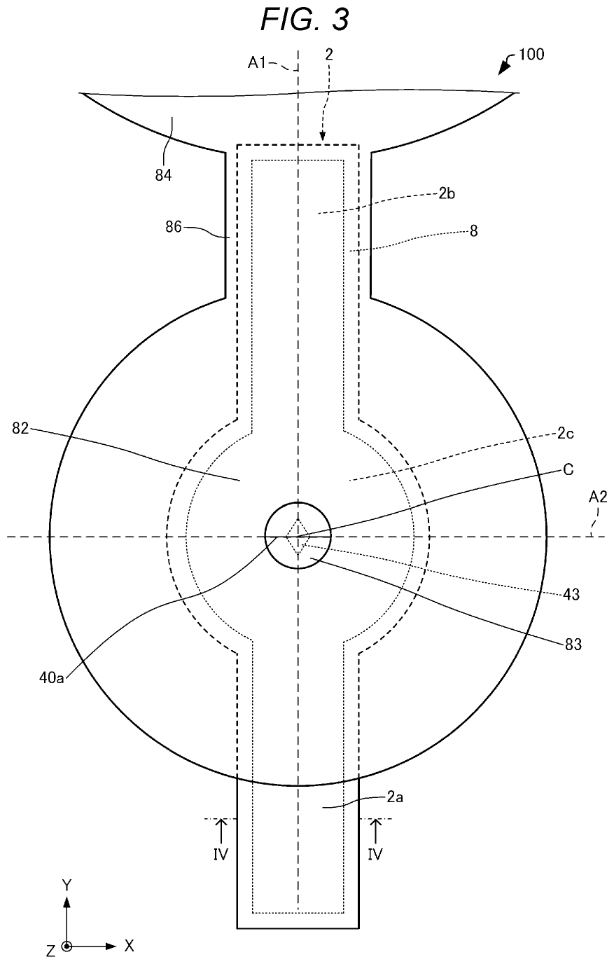

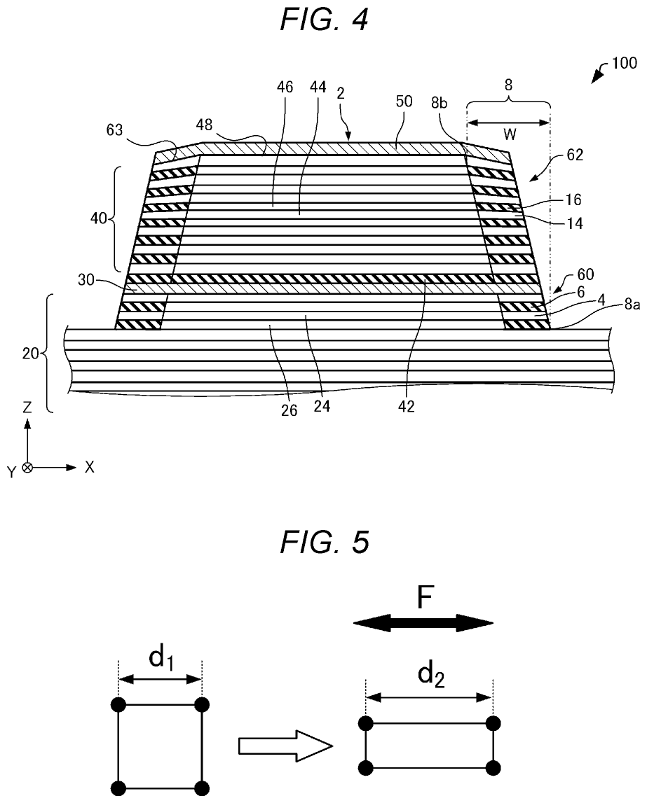

A semiconductor laser according to the present embodiment will first be described with reference to the drawings. FIG. 1 is a plan view diagrammatically showing a semiconductor laser 100 according to the present embodiment. FIG. 2 is a cross-sectional view taken along the line II-II in FIG. 1 and diagrammatically showing the semiconductor laser 100 according to the present embodiment. FIG. 3 is a plan view diagrammatically showing the semiconductor laser 100 according to the present embodiment. FIG. 4 is a cross-sectional view taken along the line IV-IV in FIG. 3 and diagrammatically showing the semiconductor laser 100 according to the present embodiment.

In FIG. 2, a laminate 2 is simplified for convenience. FIG. 3 does not show members excluding the laminate 2, a second electrode 82, a pad 84, and a drawn wiring line 86 of the semiconductor laser 100. FIGS. 1 to 4 show axes X, Y, and Z as three axes perpendicular to one another. In the present specification, the relative positional relationship in the semiconductor laser 100 will be described on the assumption that the side facing the second electrode 82 is an upper side and the side facing a substrate 10 is a lower side.

The semiconductor laser 100 is, for example, a vertical cavity surface emitting laser (VCSEL). The semiconductor laser 100 includes the substrate 10, a first mirror layer 20, an active layer 30, a second mirror layer 40, a current narrowing layer 42, a contact layer 50, a first area 60, a second area 62, a resin layer 70, a first electrode 80, and the second electrode 82, as shown in FIGS. 1 to 4.

The substrate 10 is, for example, an n-type GaAs substrate.

The first mirror layer 20 is disposed on the substrate 10. The first mirror layer 20 is disposed on a side of the active layer 30 that is the side facing the substrate 10. The first mirror layer 20 is disposed between the substrate 10 and the active layer 30. The first mirror layer 20 is, for example, an n-type semiconductor layer.

The first mirror layer 20 is a distributed Bragg reflector (DBR) mirror. The first mirror layer 20 includes high refraction index layers 24 and low refraction index layers 26, which have a refractive index smaller than the refractive index of the high refraction index layers 24, as shown in FIG. 4. The high refractive index layers 24 and the low refractive index layers 26 are alternately laminated on each other. The high refractive index layers 24 are each, for example, an n-type Al_{0.12}Ga_{0.88}As layer to which silicon has been doped. The low refractive index layers 26 contain, for example, aluminum (Al). The low refractive index layers 26 are each, for example, an n-type AlGaAs layer to which silicon has been doped. The Al atom concentration in the low refractive index layers 26 is, for example, higher than or equal to 87 at % but lower than 90 at %. The number of pairs of the high refractive index layer 24 laminated on the low refractive index layer 26 is, for example, greater than or equal to 10 but smaller than or equal to 50.

The Al atom concentration in the low refractive index layers 26 can be determined by creating a thin sectioned sample of any of the low refractive index layers 26 with a focused ion beam apparatus and performing energy dispersive X-ray analysis with a scanning transmission electron microscope. This holds also true for the Al atom concentration in low refractive index layers 46, which will be described later.

The active layer 30 is disposed on the first mirror layer 20. The active layer 30 is disposed between the first mirror layer 20 and the second mirror layer 40. The active layer 30 has, for example, a multi-quantum-well structure (MQW) structure in which three quantum well structures each formed of an i-type In_{0.06}Ga_{0.94}As layer and an i-type Al_{0.3}Ga_{0.7}As layer are layered on each other.

The second mirror layer 40 is disposed on the active layer 30. The second mirror layer 40 is disposed on a side of the active layer 30 that is the side opposite the substrate 10. The second mirror layer 40 is disposed between the active layer 30 and the contact layer 50. The second mirror layer 40 is, for example, a p-type semiconductor layer.

The second mirror layer 40 is a distributed Bragg reflector mirror. The second mirror layer 40 includes high refraction index layers 44 and low refraction index layers 46, which have a refractive index smaller than the refractive index of the high refraction index layers 44. The high refractive index layers 44 and the low refractive index layers 46 are alternately laminated on each other. The high refractive index layers 44 are each, for example, a p-type Al_{0.12}Ga_{0.88}As layer to which carbon has been doped. The low refractive index layers 46 contain, for example, aluminum (Al). The low refractive index layers 46 are each, for example, a p-type AlGaAs layer to which carbon has been doped. The Al atom concentration in the low refractive index layers 46 is, for example, higher than or equal to 87 at % but lower than 90 at %. The number of pairs of the high refractive index layer 44 laminated on the low refractive index layer 46 is, for example, greater than or equal to 3 but smaller than or equal to 40.

The second mirror layer 40, the active layer 30, and the first mirror layer 20 form a vertical-resonator-type pin diode. When voltage in the forward direction of the pin diode is applied between the first electrode 80 and the second electrode 82, electrons and holes recombine with each other in the active layer 30, resulting in light emission. The light produced in the active layer 30 undergoes multiple reflection between the first mirror layer 30 and the second mirror layer 40, resulting in stimulated emission and hence optical intensity amplification. Once the optical gain exceeds the optical loss, laser oscillation occurs, and laser light exits via the upper surface of the contact layer 50.

The current narrowing layer 42 is disposed between the first mirror layer 20 and the second mirror layer 40. The current narrowing layer 42 is disposed between the active layer 30 and the second mirror layer 40. The current narrowing layer 42 may be disposed on the active layer 30 or in the second mirror layer 40. The current narrowing layer 42 is, for example, an oxidized AlₓGa₁₋ₓAs layer, where x≥0.95. The current narrowing layer 42 is provided with an opening 43, which forms a current path. In the example shown in FIG. 3, the opening 43 has a rhombus planar shape. The opening 43 does not necessarily have a specific planar shape and may have, for example, a circular planar shape. The current narrowing layer 42 can prevent current injected into the active section 30 from spreading in the plane of the active layer 30.

The contact layer 50 is disposed on the second mirror layer 40. The contact layer 50 is a p-type semiconductor layer. Specifically, the contact layer 50 is a p-type GaAs layer to which carbon has been doped.

The first area 60 is so provided as to face the side of the first mirror layer 20, which forms the laminate 2, as shown in FIG. 4. The first area 60 includes a plurality of first oxidized layers 6, which are provided continuously with the first mirror layer 20. Specifically, the first area 60 is so configured that the first oxidized layers 6, which are oxidized layers continuous with some of the low refractive index layers 26, which form the first mirror layer 20, and lasers 4, which are continuous with some of the high refractive index layers 24, which form the first mirror layer 20, are alternately laminated with each other.

The second area 62 is so provided as to face the side of the second mirror layer 40, which forms the laminate 2. The second area 62 includes a plurality of second oxidized layers 16, which are provided continuously with the second mirror layer 40. Specifically, the second area is so configured that the second oxidized layers 16, which are oxidized layers continuous with the low refractive index layers 46, which form the second mirror layer 40, and lasers 14, which are continuous with the high refractive index layers 44, which form the second mirror layer 40, are alternately laminated with each other.

The first area 60 and the second area 62 form an oxidized area 8. The oxidized area 8 is so provided as to extend along the outer edge of the laminate 2, as shown in FIG. 3. An upper surface 63 of the oxidized area 8 inclines with respect to an upper surface 48 of the second mirror layer 40, as shown in FIG. 4. A width W of the oxidized area 8 is, for example, greater than or equal to 0.5 μm but smaller than or equal to 1.0 μm.

The width W of the oxidized area 8 refers to a distance at the side surface of the laminate 2 that is the distance between an end 8a of the lowermost layer of the plurality of oxidized layers and an end 8b of the uppermost layer of the plurality of oxidized layers, as shown in FIG. 4. The end 8a is an end of the lowermost oxidized layer of the plurality of oxidized layers that is the end opposite the low refractive index layer continuous with the lowermost oxidized layer. The end 8s forms the side surface of the laminate 2. The end 8b is an end of the uppermost oxidized layer of the plurality of oxidized layers that is the end facing the low refractive index layer continuous with the uppermost oxidized layer.

Part of the first mirror layer 20, the active layer 30, the second mirror layer 40, the current narrowing layer 42, the contact layer 50, the first area 60, and the second area 62 form the laminate 2. The laminate 2 has a columnar shape, as shown in FIG. 2. The laminate 2 is disposed on the first mirror layer 20 and protrudes upward from the first mirror layer 20. The laminate 2 is surrounded by the resin layer 70.

The laminate 2 includes a first section 2a, a second section 2b, a third section 2c in a plan view, as shown in FIG. 3. The plan view refers to a view viewed along an axis perpendicular to the substrate 10 and is, in the example shown in FIG. 3, a view viewed along the axis Z. The axis Z is an axis perpendicular to the substrate 10, and the axes X and Y are perpendicular to the axis Z and to each other.

The first section 2a, the second section 2b, the third section 2c are disposed along a first axis A1 in the plan view. The first section 2a, the second section 2b, the third section 2c are disposed on the first axis A1 in the plan view. The first axis A1 is an axis passing through a center C of the third section 2c. In the example shown in FIG. 3, the first axis A1 is parallel to the axis Y. In the plan view, the position of the center C of the third section 2c coincides with the position of the center of the opening 43.

The first section 2a, the third section 2c, and the second section 2b are arranged in the presented order along the first axis A1. The first section 2a protrudes from the third section 2c along the first axis A1 toward one side thereof. The second section 2b protrudes from the third section 2c along the first axis A1 toward the other side thereof. The first section 2a and the second section 2b have the same shape in the plan view.

The first section 2a is coupled to the third section 2c. The second section 2b is coupled to the third section 2c. That is, the first section 2a, the second section 2b, and the third section 2c are integrated with each other. The first section 2a and the second section 2b are symmetric with respect to the center C of the third section 2c.

The third section 2c is disposed between the first section 2a and the second section 2b. The third section 2c causes the light produced in the active layer 30 to resonate. That is, the third section 2c forms a resonator. The third section 2c has, for example, a circular planar shape.

In the semiconductor laser 100, the first section 2a and the second section 2b can impart strain to the active layer 30. When the first section 2a and the second section 2b impart strain to the active layer 30, tensile stress is induced in a predetermined direction in the active layer 30. As a result, the third section 2c, which forms a resonator, is not optically isotropic, and the light produced in the active layer 30 is therefore polarized. The polarization of the light produced in the active layer 30 can therefore be stabilized. The sentence “light is polarized” means that the electric field of light vibrates in a fixed direction.

The resin layer 70 is disposed at least on the side surface of the laminate 2, as shown in FIG. 2. In the example shown in FIG. 1, the resin layer 70 covers at least part of the third section 2c, the first section 2a, and the second section 2b. The resin layer 70 is made, for example, of polyimide.

The first electrode 80 is disposed on the first mirror layer 20. The first electrode 80 is in ohmic contact with the first mirror layer 20. The first electrode 80 is electrically coupled to the first mirror layer 20. The first electrode 80 is formed, for example, of a laminate of an AuGe layer, an Ni layer, a Ti layer, and an Au layer arranged in the presented order from the side facing the first mirror layer 20. The first electrode 80 is one of the electrodes for injecting current into the active layer 30. Although not shown, the first electrode 80 may be provided on the lower surface of the substrate 10.

The second electrode 82 is disposed on the contact layer 50. The second electrode 82 is in ohmic contact with the contact layer 50. The second electrode 82 is disposed also on the resin layer 70 in the example shown in FIG. 2. The second electrode 82 is electrically coupled to the second mirror layer 40 via the contact layer 50. The second electrode 82 is formed, for example, of a laminate of a Cr layer, a Pt layer, a Ti layer, a Pt layer, and an Au layer arranged in the presented order from the side facing the contact layer 50. The second electrode 82 is the other one of the electrodes for injecting current into the active layer 30.

The second electrode 82 is provided with an opening 83. The opening 83 has a circular planar shape in the example shown in FIG. 3. The opening 83 exposes a light exiting surface 52, as shown in FIG. 2. The semiconductor laser 100 outputs light via the light exiting surface 52. The light exiting surface 52 is formed of the contact layer 50 in the example shown in FIG. 2. The third section 2c has the light exiting surface 52, via which the light exits.

The second electrode 82 is electrically coupled to the pad 84, as shown in FIG. 1. The second electrode is electrically coupled to the pad 84 via the drawn wiring line 86 in the example shown in FIG. 1. The pad 84 and the drawn wiring line 86 are provided on the resin layer 70. The pad 84 and the drawn wiring line 86 is made, for example, of the same material of the second electrode 82.

The amount of strain per unit volume (for example, an amount of crystal lattice strain which is an amount of strain per crystal lattice) in the second mirror layer 40 of the third section 2c is measured in the plan view along a second axis A2 shown in FIG. 3, and the difference between the maximum of the amount of strain and the minimum thereof is greater than or equal to 0.0% but smaller than 0.20%, preferably, greater than or equal to 0.0% but smaller than or equal to 0.10%. The second axis A2 is an axis perpendicular to the first axis A1 and passing through the center C of the third section 2c in the plan view. For example, when tensile stress F is induced with respect to the second mirror layer 40 of the third section 2c in a predetermined direction as illustrated in FIG. 5, an amount of crystal lattice strain ε [%] is expressed by Expression (1) below, in which a lattice distance in a predetermined direction before the stress F is induced is d₁ and the lattice distance in the predetermined direction after the stress F is induced is d₂. Note that, FIG. 5 is a diagram explaining the amount of strain.

ε[%]=(d₂−d₁)/d₁×100 (1)

The amount of strain is measured by Raman spectrometry, as shown in an experiment example that will be described later. The range over which the amount of strain is measured is a section 40a of the second mirror layer 40 that is the section that coincides with the light exiting surface 52 in the plan view. Laser light used in Raman spectrometry is blocked by the second electrode 82 in a portion of the second mirror layer 40 that is the portion that coincides with the second electrode 82 in the plan view, and the second mirror layer 40 cannot therefore be measured. The probing laser light used in Raman spectrometry penetrates, for example, to a depth of about 100 nm. The second mirror layer 40 can therefore be measured by Raman spectrometry even when the contact layer is provided on the second mirror layer 40. In the example shown in FIG. 2, the depth is measured along the axis Z.

The semiconductor laser 100 provides, for example, the following effects and advantages.

In the semiconductor laser 100, the amount of strain per unit volume in the second mirror layer 40 of the third section 2c is measured along a second axis A2 in the plan view, and the difference between the maximum of the amount of strain and the minimum thereof is smaller than 0.20%. Occurrence of dislocation can therefore be suppressed, as shown in the experiment example, which will be described later, as compared with a case where the difference between the maximum of the amount of strain and the minimum thereof is greater than or equal to 0.20%.

In the semiconductor laser 100, the difference between the maximum of the amount of strain and the minimum thereof may be smaller than or equal to 0.10%. When the difference between the maximum of the amount of strain and the minimum thereof is smaller than or equal to 0.10%, occurrence of dislocation can be more reliably suppressed, as shown in the experiment example, which will be described later.

In the semiconductor laser 100, the Al atom concentration in the low refractive index layers 26 and 46 may be lower than 90 at %. When the Al atom concentration in the low refractive index layers 26 and 46 is lower than 90 at %, the difference between the maximum of the amount of strain and the minimum thereof can be smaller than 0.20%, as shown in the experiment example, which will be described later.

In the semiconductor laser 100, the Al atom concentration in the low refractive index layers 26 and 46 may be higher than or equal to 87 at %. When the Al atom concentration in the low refractive index layers 26 and 46 is higher than or equal to 87 at %, the polarization of the light outputted from the semiconductor laser 100 can be stabilized by a greater degree, as shown in the experiment example, which will be described later, as compared with a case where the Al atom concentration is lower than 87 at %.

### 2. Method for Manufacturing Semiconductor Laser

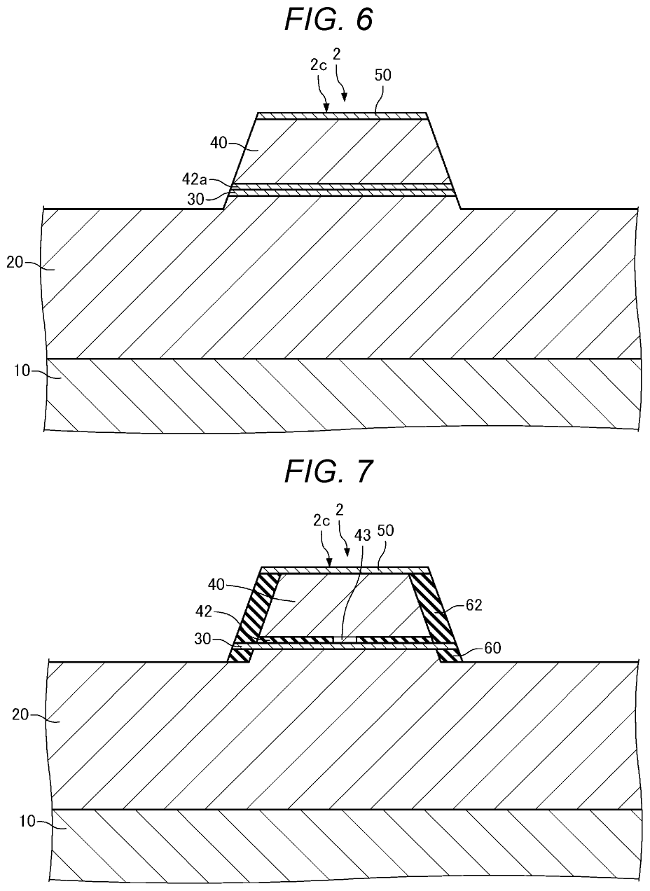

A method for manufacturing the semiconductor laser 100 according to the present embodiment will next be described with reference to the drawings. FIGS. 6 to 8 are cross-sectional views diagrammatically showing the steps of manufacturing the semiconductor laser 100 according to the present embodiment.

The first mirror layer 20, the active layer 30, an oxidization receiving layer 42a, which is oxidized to form the current narrowing layer 42, the second mirror layer 40, and the contact layer 50 are epitaxially grown on the substrate 10, as shown in FIG. 6. Examples of the epitaxial growth method may include a metal organic chemical vapor deposition (MOCVD) method and a molecular beam epitaxy (MBE) method.

The contact layer 50, the second mirror layer 40, the oxidization receiving layer 42a, the active layer 30, and the first mirror layer 20 are then patterned to form the laminate 2. The patterning is performed, for example, by photolithography and etching.

The oxidization receiving layer 42a is oxidized to form the current narrowing layer 42, as shown in FIG. 7. The oxidization receiving layer 42a is, for example, an AlₓGa₁₋ₓAs layer, where x≥0.95. For example, the AlₓGa₁₋ₓAs layer is oxidized via the side surface thereof by placing the substrate 10 on which the laminate 2 has been provided in a water vapor atmosphere at about 400° C. to form the current narrowing layer 42.

In the oxidization step in which the oxidization receiving layer 42a is oxidized to form the current narrowing layer 42, arsenide in the Al_{0.9}Ga_{0.1}As layer that forms the first mirror layer 20 is replaced with oxygen. The first oxidized layers 6 are thus formed, as shown FIG. 4. As a result, the first area 60 is formed. Similarly, arsenide in the Al_{0.9}Ga_{0.1}As layer that forms the second mirror layer 40 is replaced with oxygen. The second oxidized layers 16 are thus formed. As a result, the second area 62 is formed.

The volume of each of the first area 60 and the second area 62 decreases when arsenide is replaced with oxygen therein. The upper surface 63 of the second area 62 thus inclines. Specifically, in the first area 60 and the second area 62 in which arsenide is replaced with oxygen, the resultant strong electronegativity reduces the lattice spacing, resulting in a decrease in the volume of each of the first area 60 and the second area 62 by about 30%.

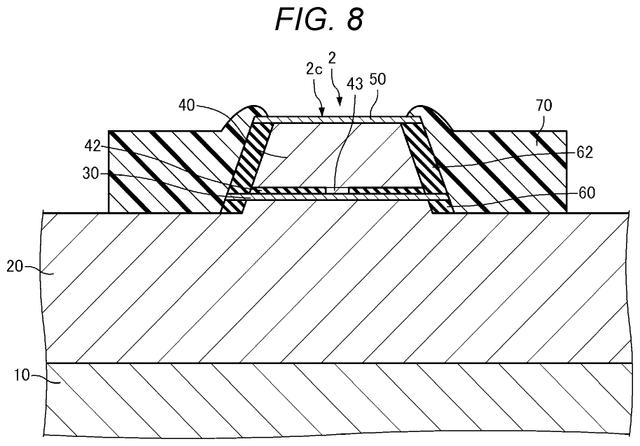

The resin layer 70 is so formed as to surround the laminate 2, as shown in FIG. 8. The resin layer 70 is formed, for example, by forming a layer made, for example, of a polyimide resin on the upper surface of the first mirror layer 20 and the entire surface of the laminate 2, for example, by using spin coating and then patterning the layer. The patterning is performed, for example, by photolithography and etching. The resin layer 70 is then cured in a heat treatment.

The second electrode 82 is formed on the contact layer 50 and the resin layer 70, and the first electrode 80 is formed on the first mirror layer 20, as shown in FIG. 2. The first electrode 80 and the second electrode 82 are formed, for example, by the combination of a vacuum evaporation method and a lift-off method. The order in accordance with which the first electrode 80 and the second electrode 82 are formed is not limited to a specific order. In the step of forming the second electrode 82, the pad 84 and the drawn wiring line 86 shown in FIG. 1 may be formed.

The semiconductor laser 100 can be manufactured by carrying out the steps described above.

### 3. Atomic Oscillator

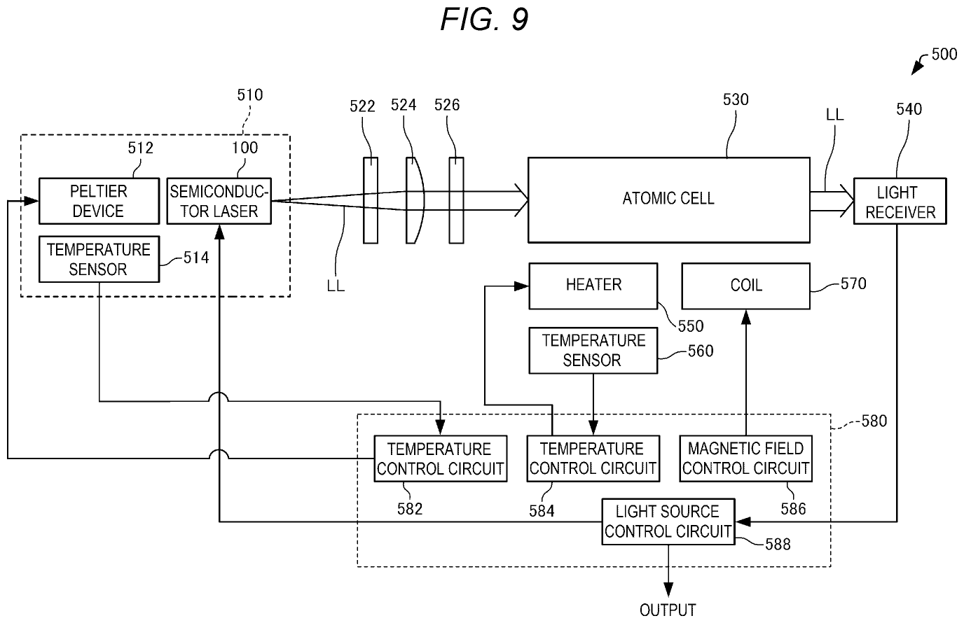

An atomic oscillator according to the present embodiment will next be described with reference to the drawings. FIG. 9 shows the configuration of an atomic oscillator 500 according to the present embodiment.

The atomic oscillator 500 is an atomic oscillator using an quantum interference effect (coherent population trapping, CPT) that produces a phenomenon in which an alkali metal atom is irradiated with two types of resonance light having different specific wavelengths at the same time and the alkali metal atom does not absorb but transmit the two types of resonance light. The phenomenon resulting from the quantum interference effect is also called an electromagnetically induced transparency (EIT) phenomenon. The atomic oscillator according to the present disclosure may instead be an atomic oscillator using a double resonance phenomenon based on light and microwaves.

The atomic oscillator 500 includes the semiconductor laser 100 according to present embodiment as a light source.

The atomic oscillator 500 includes a light emitter module 510, a light attenuation filter 522, a lens 524, a quarter wave plate 526, an atomic cell 530, a light receiver 540, a heater 550, a temperature sensor 560, a coil 570, and a control circuit 580, as shown in FIG. 9.

The light emitter module 510 includes the semiconductor laser 100, a Peltier device 512, and a temperature sensor 514. The semiconductor laser 100 outputs linearly polarized light LL containing two types of light having different frequencies. The temperature sensor 514 detects the temperature of the semiconductor laser 100. The Peltier device 512 controls the temperature of the semiconductor laser 100.

The light attenuation filter 522 attenuates the intensity of the light LL outputted from the semiconductor laser 100. The lens 524 adjusts the radiation angle of the light LL. Specifically, the lens 524 parallelizes the light LL. The quarter wave plate 526 converts each of the two types of light having different frequencies and contained in the light LL from linearly polarized light into circularly polarized light.

The atomic cell 530 is irradiated with the light outputted from the semiconductor laser 100. The atomic cell 530 transmits the light LL outputted from the semiconductor laser 100. The atomic cell 530 accommodates an alkali metal atom. The alkali metal atom has a three-level-system energy levels formed of two ground levels different from each other and an excitation level. The light LL outputted from the semiconductor laser 100 enters the atomic cell 530 via the light attenuation filter 522, the lens 524, and the quarter wave plate 526.

The light receiver 540 detects the intensity of the excitation light LL having passed through the atomic cell 530 and outputs a detection signal according to the intensity of the light. The light receiver 540 can, for example, be a photodiode.

The heater 550 controls the temperature of the atomic cell 530. The heater 550 heats the alkali metal atom accommodated in the atomic cell 530 to convert at least part of the alkali metal atom into a gaseous alkali metal atom.

The temperature sensor 560 detects the temperature of the atomic cell 530. The coil 570 produces a magnetic field that causes a plurality of degenerated energy levels of the alkali metal atom in the atomic cell 530 to undergo Zeeman splitting. The coil 570 enlarges based on Zeeman splitting the gap between degenerated different energy levels of the alkali metal atom for improvement in resolution. As a result, the accuracy of the oscillation frequency of the atomic oscillator 500 can be increased.

The control circuit 580 includes a temperature control circuit 582, a temperature control circuit 584, a magnetic field control circuit 586, and a light source control circuit 588.

The temperature control circuit 582 controls energization of the Peltier device 512 based on the result of the detection performed by the temperature sensor 514 in such a way that the semiconductor laser 100 has a desired temperature. The temperature control circuit 584 controls energization of the heater 550 based on the result of the detection performed by the temperature sensor 560 in such a way that a desired temperature is achieved in the atomic cell 530. The magnetic field control circuit 586 controls the energization of the coil 570 in such a way that the coil 570 produces a constant magnetic field.

The light source control circuit 588 controls the frequencies of the two types of light contained in the light LL outputted from the semiconductor laser 100 based on the result of the detection performed by the light receiver 540 in such a way that the EIT phenomenon occurs. The EIT phenomenon occurs when the two types of light form a resonant light pair having a frequency difference corresponding to the energy difference between the two ground levels of the alkali metal atom accommodated in the atomic cell 530. The light source control circuit 588 includes a voltage controlled oscillator (VCO) having an oscillation frequency so controlled as to be stabilized in synchronization with the control of the frequencies of the two types of light, and the light source control circuit 588 outputs an output signal from the voltage controlled oscillator as the clock signal from the atomic oscillator 500.

The control circuit 580 is, for example, provided in an IC (integrated circuit) chip mounted on a substrate that is not shown. The control circuit 580 may be a single IC or the combination of a plurality of digital circuits or analog circuits.

The semiconductor laser 100 is not necessarily used as the light source of an atomic oscillator. The semiconductor laser 100 may be used, for example, as a laser for communication or distance measurement.

### 4. Frequency Signal Generation System

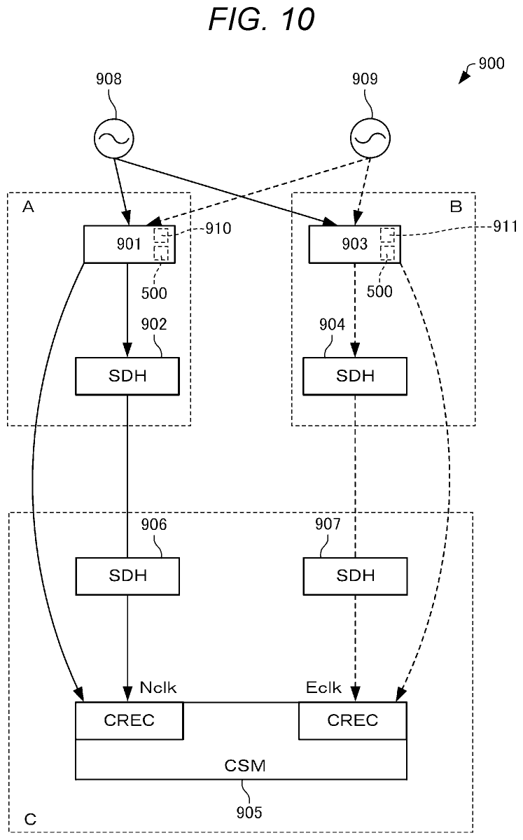

A frequency signal generation system according to the present embodiment will next be described with reference to the drawings. The following clock transmission system as a timing server is an example of the frequency signal generation system. FIG. 10 is a schematic configuration diagram showing a clock transmission system 900.

The clock transmission system 900 includes the atomic oscillator 500 according to the present embodiment.

The clock transmission system 900 is a system that causes clocks used in apparatuses in a time division multiplex network to coincide with one another and has a normal-system (N-system) and emergency-system (E-system) redundant configuration.

The clock transmission system 900 includes a clock supply apparatus 901 and a synchronous digital hierarchy (SDH) apparatus 902 in a station A, a clock supply apparatus 903 and an SDH apparatus 904 in a station B, and a clock supply apparatus 905 and an SDH apparatus 906, 907 in a station C, as shown in FIG. 10. The clock supply apparatus 901 includes the atomic oscillator 500 and generates an N-system clock signal Nclk. The clock supply apparatus 901 includes a terminal 910, to which a frequency signal from the atomic oscillator 500 is inputted. The atomic oscillator 500 in the clock supply apparatus 901 generates the clock signal in synchronization with more precise clock signals from master clocks 908 and 909 each including a cesium-based atomic oscillator.

The SDH apparatus 902 transmits and receives a primary signal, superimposes the N-system clock signal Nclk on the primary signal, and transmits the resultant signal to the lower-level clock supply apparatus 905 based on the clock signal from the clock supply apparatus 901. The clock supply apparatus 903 includes the atomic oscillator 500 and generates an E-system clock signal Eclk. The clock supply apparatus 903 includes a terminal 911, to which a frequency signal from the atomic oscillator 500 is inputted. The atomic oscillator 500 in the clock supply apparatus 903 generates the clock signal in synchronization with the more precise clock signals from the master clocks 908 and 909 each including a cesium-based atomic oscillator.

The SDH apparatus 904 transmits and receives a primary signal, superimposes the E-system clock signal Eclk on the primary signal, and transmits the resultant signal to the lower-level clock supply apparatus 905 based on the clock signal from the clock supply apparatus 903. The clock supply apparatus 905 receives the clock signals from the clock supply apparatuses 901 and 903 and generates a clock signal in synchronization with the received clock signals.

The clock supply apparatus 905 usually generates the clock signal in synchronization with the N-system clock signal Nclk from the clock supply apparatus 901. When abnormality occurs in the N system, the clock supply apparatus 905 generates the clock signal in synchronization with the E-system clock signal Eclk from the clock supply apparatus 903. Switching from the N system to the E system as described above allows stable clock supply to be ensured and the reliability of the clock path network to be enhanced. The SDH apparatus 906 transmits and receives a primary signal based on the clock signal from the clock supply apparatus 905. Similarly, the SDH apparatus 907 transmits and receives a primary signal based on the clock signal from the clock supply apparatus 905. The apparatuses in the station C can thus be synchronized with the apparatuses in the station A or B.

The frequency signal generation system according to the present embodiment is not limited to the clock transmission system. The frequency signal generation system includes any system that incorporates an atomic oscillator and is formed of a variety of apparatuses and a plurality of apparatuses using the frequency signal from the atomic oscillator. The frequency signal generation system includes a controller that controls the atomic oscillator.

The frequency signal generation system according to the present embodiment may instead, for example, be a smartphone, a tablet terminal, a timepiece, a mobile phone, a digital still camera, a liquid ejection apparatus, such as an inkjet printer, a personal computer, a television receiver, a video camcorder, a video tape recorder, a car navigator, a pager, an electronic notepad, an electronic dictionary, a desktop calculator, an electronic game console, a word processor, a workstation, a TV phone, a security television monitor, electronic binoculars, a point-of-sales (POS) terminal, a medical apparatus, a fish finder, a global navigation satellite system (GNSS) frequency standard, a variety of measuring apparatuses, a variety of instruments, a flight simulator, a ground digital broadcast system, a mobile phone base station, and a vehicle.

Examples of the medical apparatus may include an electronic thermometer, a blood pressure gauge, a blood sugar meter, an electrocardiograph, an ultrasonic diagnostic apparatus, an electronic endoscope, and a magnetocardiograph. Examples of the variety of instruments may include a variety of instruments in an automobile, an airplane, and a ship. Examples of the vehicle may include an automobile, an airplane, and a ship.

### 5. Experiment Example

### 5.1 Line Profile of Amount of Strain

### 5.1.1 Experiment Conditions

A VCSEL including the first section and the second section (hereinafter also referred to as “VCSEL with blades”) was prepared, as in the case of the semiconductor laser 100 shown in FIGS. 1 to 4, and lattice vibration of the second mirror layer of the VCSEL was detected by using Raman spectrometry.

Raman spectrometry was performed by using “Nanofinder30” (“Nanofinder” is registered trademark) manufactured by TOKYO INSTRUMENTS, INC. A diode pumped solid-state (DPSS) laser was used as the probing laser, and the wavelength of the laser light was set at 458 nm. The focal length was set at 52 cm. The diffraction grating was so set as to have 3600 lines/mm. Raman spectrometry allows detection to a depth of about 100 nm and has a resolution of 0.03%.

Attention was paid to the peak of the vibration mode of GaAs-LO phonon (LO: longitudinal optical) in the vicinity of 290 cm⁻¹ in a Raman spectrum. Let Δω_{LO} [cm⁻¹] be a shift amount of the peak that linearly shifts by receiving the strain, and the amount of crystal lattice strain ε [%] of the second mirror layer was determined based on Expression (2) below.

ε=Δω_{LO}/(−5.2) (2)

The peak shift amount Δω_{LO} in an absolute value Xω_{LO} of a peak position of the vibration mode of GaAs-LO phonon of the second mirror layer of the VCSEL with blades with respect to a pre-measured peak position Bω_{LO} of the vibration mode of GaAs-LO phonon of a GaAs substrate with no strain was determined based on Expression (3) below. The GaAs substrate having no strain in the present experiment example was a (100) substrate cut from a single-crystal GaAs ingot manufactured by Wefer Technology Ltd.

Δω_{LO}=Xω_{LO}−Bω_{LO} (3)

The surface of the VCSEL with blades was then scanned with “Nanofinder30” at a 0.5-μm step along the second axis A2 shown in FIG. 3 to acquire a line profile of the amount of strain ε [%] based on Expressions (2) and (3) described above. Similarly, the surface of the VCSEL with blades was scanned at the 0.5-μm step along the first axis A1 shown in FIG. 3 to acquire a line profile of the amount of strain ε [%].

Further, a VCSEL including no first section or second section (hereinafter also referred to as “VCSEL with no blade”) was prepared, a line profile of the amount of strain ε [%] was acquired, as in the case of the VCSEL with blades.

### 5.1.2 Results of Experiment

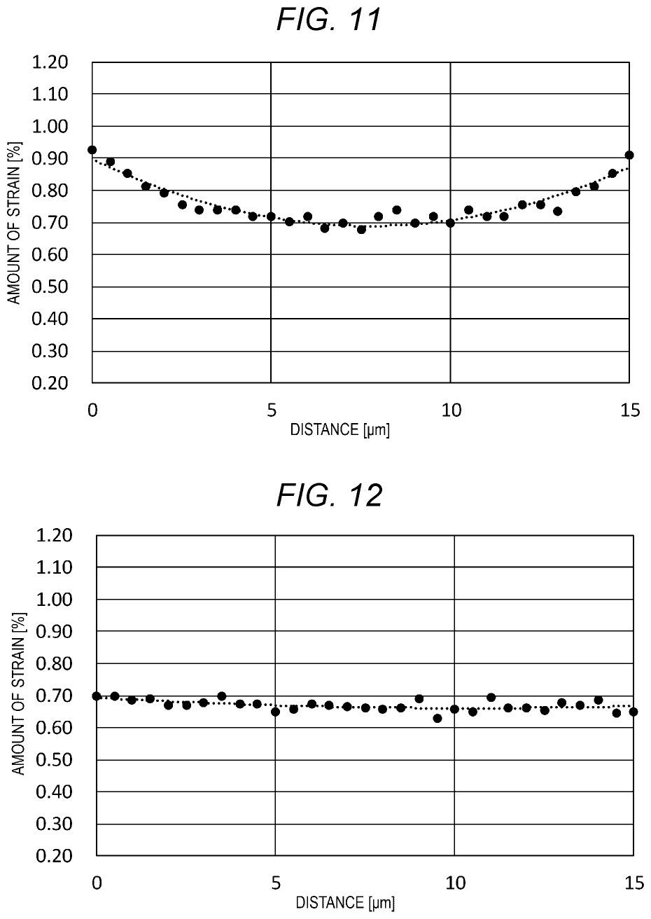

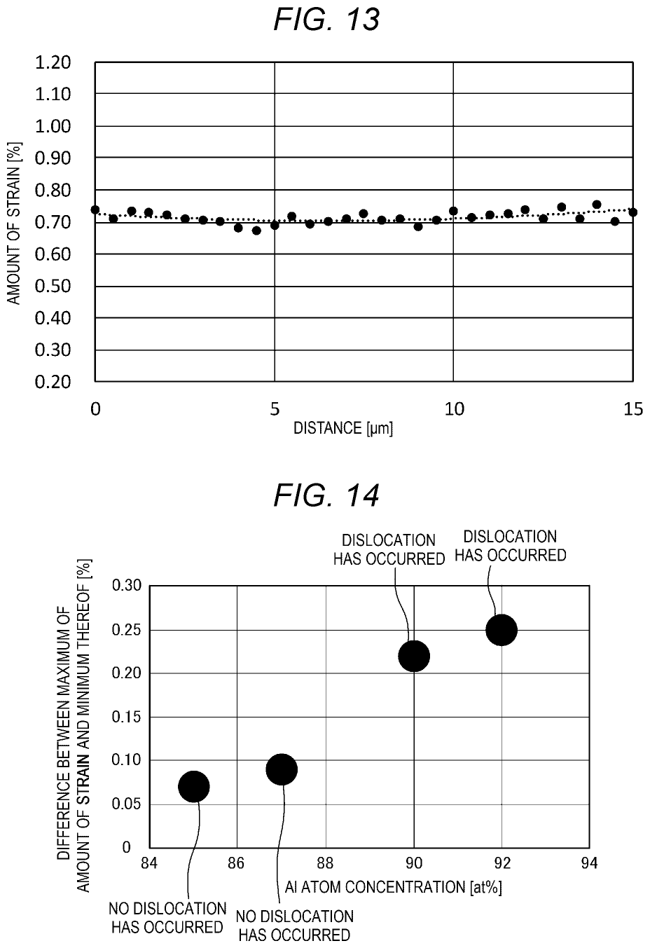

FIGS. 11 to 13 show graphs each illustrating a line profile of the amount of strain. FIG. 11 shows the line profile along the second axis A2 of the VCSEL with blades. FIG. 12 shows the line profile along the first axis A1 of the VCSEL with blades. FIG. 13 shows the line profile along the second axis A2 of the VCSEL with no blade. In FIGS. 11 to 13, the broken line represents a quadratic polynomial approximate curve of the acquired amount of strain.

In the VCSEL with blades, the nearer to an end of the resonance section in the direction along the second axis A2, the greater the amount of strain, and therefore the greater the difference in the amount of strain between the center and the ends of the resonator, as shown in FIG. 11. In contrast, the line profile of the amount of strain of the VCSEL with blades along the first axis A1 does not greatly differ from the profile of the VCSEL with no blade shown in FIG. 13, as shown in FIG. 12. The line profile of the amount of strain of the VCSEL with no blade along the first axis A1 is not shown but is basically the same as the profile in FIG. 13.

### 5.2 Relationship Between Amount of Strain and Dislocation

### 5.2.1 Experiment Conditions

VCSELs with blades were so created that the Al atom concentration in the low refractive index layers (AlGaAs layers) in the first and second mirror layers was 0.85, 0.87, 0.90, and 0.92, and the line profiles were acquired along the second axis A2 in the same manner as described above. A quadratic polynomial approximate curve was created for each of the line profiles, and the difference between the maximum of the amount of strain and the minimum thereof was calculated for each of the quadratic polynomial approximate curves.

Further, whether or not dislocation has occurred in each of the four types of VCSEL with blades described above was checked. Whether or not dislocation has occurred was checked by processing a cross section of each of the VCSELs with blades with a focused ion beam apparatus and observing a scanning transmission electron microscopy-low-angle annular dark-field (STEM-LAADF) image under a scanning transmission electron microscope. The focused ion beam apparatus was “Helios NanoLab 600i” manufactured by Thermo Fisher Scientific Inc. The scanning transmission electron microscope was “JEM-ARM200F ACCELARM” manufactured by JOEL Ltd.

### 5.2.2 Results of Experiment

FIG. 14 show graphs illustrating the relationship between the Al atom concentration and the difference between the maximum of the amount of strain and the minimum thereof. FIG. 14 further shows whether or not dislocation has occurred.

It is ascertained, as shown in FIG. 14, that dislocation occurs when the difference between the maximum of the amount of strain and the minimum thereof is greater than or equal to 0.20%, and that no dislocation occurs when the difference is smaller than 0.20%. Further, it is shown that the higher the Al atom concentration in the low refractive index layers of the mirror layers, the greater the difference between the maximum of the amount of strain and the minimum thereof.

### 5.3 Polarization

### 5.3.1 Experiment Conditions

VCSELs with blades were so prepared that the Al atom concentration in the low refractive index layers in the mirror layers was 0.85, 0.87, 0.90, and 0.92, as described above, with the number of thus prepared VCSELs being 500 for each of the Al atom concentrations. The VCSELs was so designed that the polarization direction of the light therefrom is a first direction. Current was injected into the VCSELs to cause the VCSELs to emit light, and the proportion of VCSELs that emit light having the polarization direction being neither the first direction nor a second direction perpendicular to the first direction was determined as a polarization difference ratio. It is believed that the greater the polarization difference ratio, the more unstable the polarization.

### 5.3.2 Results of Experiment

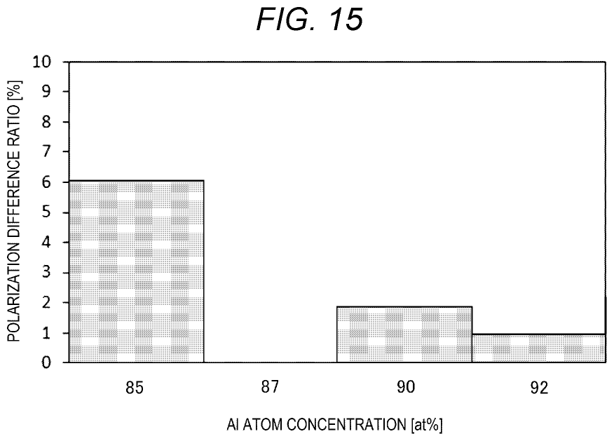

FIG. 15 shows graphs illustrating the relationship between the Al atom concentration and the polarization difference ratio. FIG. 15 shows that the polarization difference ratio is large when the Al atom concentration is 85 at %, and that the polarization difference ratio can be suppressed to a value smaller than or equal to 2% when the Al atom concentration is higher than or equal to 87 at %. FIGS. 14 and 15 show that the polarization of the outputted light can be stabilized by a greater amount and dislocation can be suppressed when the Al atom concentration is higher than or equal to 87 at % but smaller than 90 at %.

The present disclosure encompasses substantially the same configuration as the configuration described in the embodiment, for example, a configuration having the same function, using the same method, and providing the same result or a configuration having the same purpose and providing the same effect. Further, the present disclosure encompasses a configuration in which an inessential portion of the configuration described in the embodiment is replaced. Moreover, the present disclosure encompasses a configuration that provides the same effects and advantages as those provided by the configuration described in the embodiment or a configuration that can achieve the same purpose as that achieved by the configuration described in the embodiment. Further, the present disclosure encompasses a configuration in which a known technology is added to the configuration described in the embodiment.

The following contents are derived from the embodiment and variations described above.

A semiconductor laser according to an aspect includes a first mirror layer, a second mirror layer, an active layer disposed between the first mirror layer and the second mirror layer, a first area provided continuously with the first mirror layer and including a plurality of first oxidized layers, and a second area provided continuously with the second mirror layer and including a plurality of second oxidized layers. The first mirror layer, the second mirror layer, the active layer, the first area, and the second area form a laminate. The laminate includes in the plan view a first section, a second section, and a third section disposed between the first section and the second section along a first axis and causing light produced in the active layer to resonate. The amount of strain per unit volume in the second mirror layer of the third section is measured along a second axis perpendicular to the first axis and passing through the center of the third section in the plan view, and the difference between the maximum of the amount of strain and the minimum thereof is smaller than 0.20%.

According to the semiconductor laser described above, occurrence of dislocation can be suppressed as compared with a case where the difference between the maximum of the amount of strain and the minimum thereof is greater than or equal to 0.20%.

In the semiconductor laser according to the aspect, the difference may be smaller than or equal to 0.10%.

According to the semiconductor laser described above, occurrence of dislocation can be more reliably suppressed.

In the semiconductor laser according to the aspect, the first mirror layer and the second mirror layer may each include high refraction index layers and low refraction index layers having a refractive index smaller than the refractive index of the high refraction index layers and containing Al. The high refractive index layers and the low refractive index layers may be alternately laminated on each other. The Al atom concentration in the low refractive index layers may be lower than 90 at %.

According to the semiconductor laser described above, the difference between the maximum of the amount of strain and the minimum thereof can be smaller than or equal to 0.20%.

In the semiconductor laser according to the aspect, the Al atom concentration in the low refractive index layers may be higher than or equal to 87 at %.

According to the semiconductor laser described above, the polarization of the light outputted from the semiconductor laser can be stabilized by a greater degree.

In the semiconductor laser according to the aspect, the third section may have a light exiting surface via which the light exits, and the range over which the amount of strain is measured may be a section of the second mirror layer that is the section that coincides with the light exiting surface.

The semiconductor laser according to the aspect may include a substrate, and the first mirror layer may be disposed between the substrate and the active layer.

An atomic oscillator according to another aspect includes a semiconductor laser, an atomic cell irradiated with light outputted from the semiconductor laser and accommodating an alkali metal atom, and a light receiver that detects the intensity of the light passing through the atomic cell and outputs a detection signal. The semiconductor laser includes a first mirror layer, a second mirror layer, an active layer disposed between the first mirror layer and the second mirror layer, a first area provided continuously with the first mirror layer and including a plurality of first oxidized layers, and a second area provided continuously with the second mirror layer and including a plurality of second oxidized layers. The first mirror layer, the second mirror layer, the active layer, the first area, and the second area form a laminate. The laminate includes in the plan view a first section, a second section, and a third section disposed between the first section and the second section along a first axis and causing light produced in the active layer to resonate. The amount of strain per unit volume in the second mirror layer of the third section is measured along a second axis perpendicular to the first axis and passing through the center of the third section in the plan view, and the difference between the maximum of the amount of strain and the minimum thereof is smaller than 0.20%.

What is claimed is:

1. A semiconductor laser comprising:
a first mirror layer;
a second mirror layer;
an active layer disposed between the first mirror layer and the second mirror layer;
a first area provided continuously with the first mirror layer and including a plurality of first oxidized layers; and
a second area provided continuously with the second mirror layer and including a plurality of second oxidized layers,
wherein the first mirror layer, the second mirror layer, the active layer, the first area, and the second area form a laminate,
the laminate includes in the plan view
a first section,
a second section, and
a third section disposed between the first section and the second section along a first axis and causing light produced in the active layer to resonate, and
an amount of strain per unit volume in the second mirror layer of the third section is measured along a second axis perpendicular to the first axis and passing through a center of the third section in the plan view, and a difference between a maximum of the amount of strain and a minimum thereof is smaller than 0.20%.

2. The semiconductor laser according to claim 1,
wherein the difference is smaller than or equal to 0.10%.

3. The semiconductor laser according to claim 1,
wherein the first mirror layer and the second mirror layer each include
high refraction index layers, and
low refraction index layers having a refractive index smaller than a refractive index of the high refraction index layers and containing Al,
the high refractive index layers and the low refractive index layers are alternately laminated on each other, and
Al atom concentration in the low refractive index layers is lower than 90 at %.

4. The semiconductor laser according to claim 3,
wherein the Al atom concentration in the low refractive index layers is higher than or equal to 87 at %.

5. The semiconductor laser according to claim 1,
wherein the third section has a light exiting surface via which the light exits, and
a range over which the amount of strain is measured is a section of the second mirror layer that is a section that coincides with the light exiting surface.

6. The semiconductor laser according to claim 1,
further comprising a substrate,
wherein the first mirror layer is disposed between the substrate and the active layer.

7. An atomic oscillator comprising:
a semiconductor laser;
an atomic cell irradiated with light outputted from the semiconductor laser and accommodating an alkali metal atom; and
a light receiver that detects intensity of light passing through the atomic cell and outputs a detection signal,
wherein the semiconductor laser includes
a first mirror layer,
a second mirror layer,
an active layer disposed between the first mirror layer and the second mirror layer,
a first area provided continuously with the first mirror layer and including a plurality of first oxidized layers, and
a second area provided continuously with the second mirror layer and including a plurality of second oxidized layers,
the first mirror layer, the second mirror layer, the active layer, the first area, and the second area form a laminate,
the laminate includes in the plan view
a first section,
a second section, and
a third section disposed between the first section and the second section along a first axis and causing light produced in the active layer to resonate, and
an amount of strain per unit volume in the second mirror layer of the third section is measured along a second axis perpendicular to the first axis and passing through a center of the third section in the plan view, and a difference between the maximum of the amount of strain and the minimum thereof is smaller than 0.20%.
